(19) United States
(12) Patent Application Publication
(10) Pub. No.: US 2013/0243971 A1
(43) Pub. Date: Sep. 19, 2013

(54) Apparatus and Process for Atomic Layer Deposition with Horizontal Laser

(71) Applicants: David Thompson, San Jose, CA (US); Pravin K. Narwankar, Sunnyvale, CA (US); Swaminathan Srinivasan, Pleasanton, CA (US); Sukti Chatterjee, Cupertino, CA (US); Abhilash Mayur, Salinas, CA (US); Kashif Maqsood, San Francisco, CA (US)

(72) Inventors: David Thompson, San Jose, CA (US); Pravin K. Narwankar, Sunnyvale, CA (US); Swaminathan Srinivasan, Pleasanton, CA (US); Sukti Chatterjee, Cupertino, CA (US); Abhilash Mayur, Salinas, CA (US); Kashif Maqsood, San Francisco, CA (US)

(73) Assignee: Applied Materials, Inc., Santa Clara, CA (US)

(21) Appl. No.: 13/420,164

(22) Filed: Mar. 14, 2012

(51) Int. Cl. C23C 16/455; C23C 16/56

(52) U.S. Cl. 427/554; 118/723 R

(57) ABSTRACT

Provided are atomic layer deposition apparatus and methods including a gas distribution plate and at least one laser source emitting a laser beam adjacent the gas distribution plate to activate gaseous species from the gas distribution plate. Also provided are gas distribution plates with elongate gas injector ports where the at least one laser beam is directed along the length of the elongate gas injectors.

### BACKGROUND

Embodiments of the invention generally relate to an apparatus and a method for depositing materials. More specifically, embodiments of the invention are directed to a atomic layer deposition chambers with linear reciprocal motion.

In the field of semiconductor processing, flat-panel display processing or other electronic device processing, vapor deposition processes have played an important role in depositing materials on substrates. As the geometries of electronic devices continue to shrink and the density of devices continues to increase, the size and aspect ratio of the features are becoming more aggressive, e.g., feature sizes of 0.07 μm and aspect ratios of 10 or greater. Accordingly, conformal deposition of materials to form these devices is becoming increasingly important.

During an atomic layer deposition (ALD) process, reactant gases are introduced into a process chamber containing a substrate. Generally, a first reactant is introduced into a process chamber and is adsorbed onto the substrate surface. A second reactant is introduced into the process chamber and reacts with the first reactant to form a deposited material. A purge step may be carried out to ensure that the only reactions that occur are on the substrate surface. The purge step may be a continuous purge with a carrier gas or a pulse purge between the delivery of the reactant gases.

There is an ongoing need in the art for improved apparatuses and methods for processing substrates by atomic layer deposition.

### SUMMARY

One or more embodiments of the invention are directed to deposition systems comprising a processing chamber, a gas distribution plate in the processing chamber and at least one laser source. The gas distribution plate has a plurality of elongate gas ports that direct flows of gases toward a surface of a substrate. The at least one laser source emits a laser beam directed along at least one of the elongate gas ports between the gas distribution plate and the substrate.

In some embodiments, the gas distribution plate comprises a plurality of first reactive gas injectors that direct flows of a first reactive gas toward a substrate and at least one second reactive gas injector that directs a flow of a second reactive gas different from the first reactive gas toward a substrate. In one or more embodiments, the at least one laser beam is directed along the length of one or more of each of the first reactive gas injectors and the at least one second reactive gas injectors.

In some embodiments, there is one laser source. In one or more embodiments, the one laser source emits a beam that is split with at least one beam splitter to direct the one laser beam along multiple elongate gas injector.

In some embodiments, there are at least two laser sources emitting laser beams and each laser beam is directed along a different elongate gas injector.

In some embodiments, the laser source is located outside of the processing chamber and the laser beam is directed through a window in a wall of the processing chamber. In one or more embodiments, the window is heated. Some embodiments further comprise a purge gas flow between the window and the gas distribution plate.

Additional embodiments of the invention are directed to deposition systems comprising a processing chamber, a gas distribution plate in the processing chamber and at least one laser source. The gas distribution plate directs flows of gases toward a surface of a substrate. The at least one laser source has a laser beam directed along a path adjacent to the gas distribution plate between the gas distribution plate and the substrate.

In some embodiments, there is one laser source and the system further comprises at least one beam splitter that directs the one laser beam along multiple paths.

In some embodiments, there are at least two lasers sources emitting at least two laser beams. One or more embodiments further comprise at least one beam splitter that directs at least one of the at least two lasers beams along multiple paths.

In some embodiments, the at least one laser source is positioned so that when a substrate is present in the system, the laser beam is up to about 50 mm from the substrate.

In some embodiments, the laser beam is one of a continuous laser and a pulsed laser.

Further embodiments of the invention are directed to methods of processing a substrate. The substrate is sequentially contacted with a flow of a first precursor and a flow of a second precursor from a gas distribution plate to form a layer on the substrate. At least one of the first precursor and the second precursor is activated with at least one laser beam directed adjacent the gas distribution plate.

In some embodiments, each of the first precursor and second precursor flow from separate elongate gas ports and the at least one laser beam is directed along a length of at least one of the elongate gas ports.

Some embodiments further comprise pulsing the laser beam to coincide with the flow of one or more of the first precursor and the second precursor.

### BRIEF DESCRIPTION OF THE DRAWINGS

So that the manner in which the above recited features of the invention are attained and can be understood in detail, a more particular description of the invention, briefly summarized above, may be had by reference to the embodiments thereof which are illustrated in the appended drawings. It is to be noted, however, that the appended drawings illustrate only typical embodiments of this invention and are therefore not to be considered limiting of its scope, for the invention may admit to other equally effective embodiments.

FIG. 1 shows a schematic side view of an atomic layer deposition chamber according to one or more embodiments of the invention;

FIG. 2 shows a susceptor in accordance with one or more embodiments of the invention;

FIG. 3 show a partial perspective view of an atomic layer deposition chamber in accordance with one or more embodiments of the invention;

FIG. 4 shows a schematic cross-sectional view of a gas distribution plate in accordance with one or more embodiments of the invention;

FIG. 5 shows a schematic cross-sectional view of a gas distribution plate and horizontal lasers in accordance with one or more embodiments of the invention;

FIG. 6 shows a schematic cross-sectional view of a gas distribution plate and horizontal lasers in accordance with one or more embodiments of the invention;

FIG. 7 shows a schematic cross-sectional view of a gas distribution plate and horizontal lasers in accordance with one or more embodiments of the invention;

FIG. 8 shows a schematic cross-sectional view of a gas distribution plate and horizontal lasers in accordance with one or more embodiments of the invention;

FIG. 9 shows a schematic cross-sectional view of a gas distribution plate in accordance with one or more embodiments of the invention;

FIG. 10 shows a schematic view showing the arrangement of lasers with respect to a gas distribution plate in accordance with one or more embodiments of the invention;

FIG. 11 shows a schematic view showing the arrangement of lasers with respect to a gas distribution plate in accordance with one or more embodiments of the invention;

FIG. 12 shows a schematic view showing the arrangement of lasers with respect to a gas distribution plate in accordance with one or more embodiments of the invention; and

FIG. 13 shows a cluster tool in accordance with one or more embodiment of the invention.

### DETAILED DESCRIPTION

Embodiments of the invention are directed to atomic layer deposition apparatus and methods which provide improved movement of substrates. Some embodiments of the invention are directed to atomic layer deposition apparatuses (also called cyclical deposition) incorporating a gas distribution plate, reciprocal linear motion and a horizontal laser.

Embodiments of the invention use one or more lasers to stimulate gaseous precursors in and ALD reactor where the precursors are introduced horizontally separated. This may have the advantage of increasing the efficiency of precursor decomposition, increase the rate of saturation and/or initiate/catalyze the reaction. Current ALD processes are challenged by process speed with delays due to time consumed in emptying and refilling of the two precursors which are sequentially introduced to the reactor. Embodiments of invention apply to the use of pyrolitic (thermal) and photolytic assist using lasers of different wavelength (IR, UV-excimer lasers) to effectively dissociate through direct dissociation or catalytic decomposition of precursors.

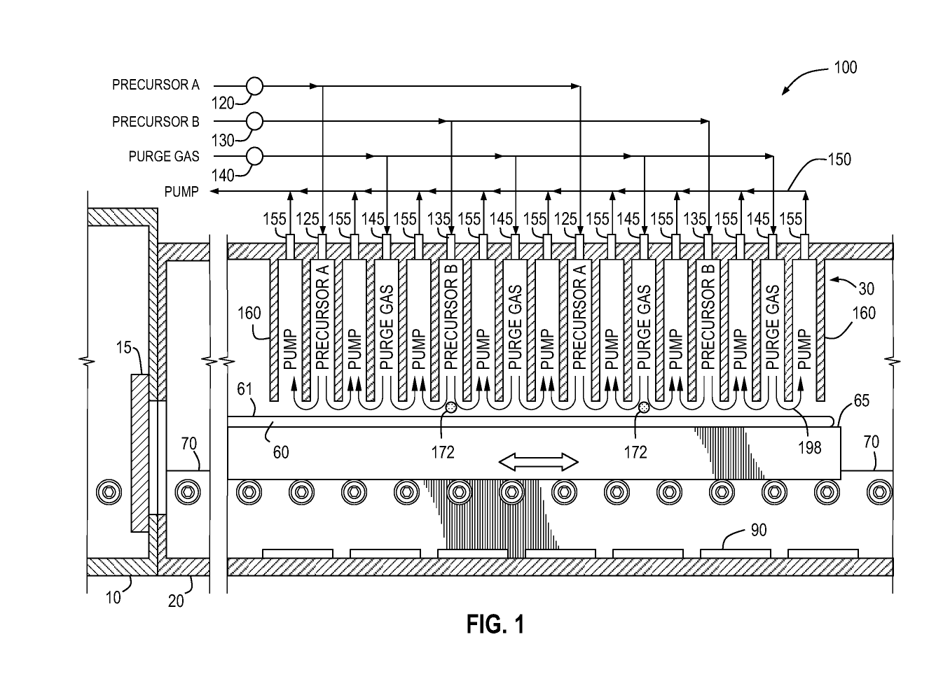

FIG. 1 is a schematic cross-sectional view of an atomic layer deposition system 100 or reactor in accordance with one or more embodiments of the invention. The system 100 includes a load lock chamber 10 and a processing chamber 20. The processing chamber 20 is generally a sealable enclosure, which is operated under vacuum, or at least low pressure. The processing chamber 20 is isolated from the load lock chamber 10 by an isolation valve 15. The isolation valve 15 seals the processing chamber 20 from the load lock chamber 10 in a closed position and allows a substrate 60 to be transferred from the load lock chamber 10 through the valve to the processing chamber 20 and vice versa in an open position.

The system 100 includes a gas distribution plate 30 capable of distributing one or more gases across a substrate 60. The gas distribution plate 30 can be any suitable distribution plate known to those skilled in the art, and specific gas distribution plates described should not be taken as limiting the scope of the invention. The output face of the gas distribution plate 30 faces the first surface 61 of the substrate 60.

Substrates for use with the embodiments of the invention can be any suitable substrate. In some embodiments, the substrate is a rigid, discrete, generally planar substrate. As used in this specification and the appended claims, the term “discrete” when referring to a substrate means that the substrate has a fixed dimension. The substrate of some embodiments is a semiconductor wafer, such as a 200 mm or 300 mm diameter silicon wafer.

The gas distribution plate 30 comprises a plurality of gas ports that transmit one or more gas streams to the substrate 60 and a plurality of vacuum ports disposed between each gas port that transmit the gas streams out of the processing chamber 20. In the embodiment of FIG. 1, the gas distribution plate 30 comprises a first precursor injector 120, a second precursor injector 130 and a purge gas injector 140. The injectors 120, 130, 140 may be controlled by a system computer (not shown), such as a mainframe, or by a chamber-specific controller, such as a programmable logic controller. The precursor injector 120 is configured to inject a continuous (or pulse) stream of a reactive precursor of compound A into the processing chamber 20 through a plurality of gas ports 125. The precursor injector 130 is configured to inject a continuous (or pulse) stream of a reactive precursor of compound B into the processing chamber 20 through a plurality of gas ports 135. The purge gas injector 140 is configured to inject a continuous (or pulse) stream of a non-reactive or purge gas into the processing chamber 20 through a plurality of gas ports 145. The purge gas helps remove reactive material and reactive by-products from the processing chamber 20. The purge gas is typically an inert gas, such as, nitrogen, argon and helium. Gas ports 145 are disposed in between gas ports 125 and gas ports 135 so as to separate the precursor of compound A from the precursor of compound B, thereby avoiding cross-contamination between the precursors and prevent gas-phase reactions.

In another aspect, a remote plasma source (not shown) may be connected to the precursor injector 120 and the precursor injector 130 prior to injecting the precursors into the chamber 20. The plasma of reactive species may be generated by applying an electric field to a compound within the remote plasma source. Any power source that is capable of activating the intended compounds may be used. For example, power sources using DC, radio frequency (RF), and microwave (MW) based discharge techniques may be used. If an RF power source is used, it can be either capacitively or inductively coupled. The activation may also be generated by a thermally based technique, a gas breakdown technique, a high intensity light source (e.g., UV energy), or exposure to an x-ray source. Exemplary remote plasma sources are available from vendors such as MKS Instruments, Inc. and Advanced Energy Industries, Inc.

The system 100 further includes a pumping system 150 connected to the processing chamber 20. The pumping system 150 is generally configured to evacuate the gas streams out of the processing chamber 20 through one or more vacuum ports 155. The vacuum ports 155 are disposed between each gas port so as to evacuate the gas streams out of the processing chamber 20 after the gas streams react with the substrate surface and to further limit cross-contamination between the precursors.

The system 100 includes a plurality of partitions 160 disposed on the processing chamber 20 between each port. A lower portion of each partition extends close to the first surface 61 of substrate 60, for example about 0.5 mm from the first surface 61, This distance should be such that the lower portions of the partitions 160 are separated from the substrate surface by a distance sufficient to allow the gas streams to flow around the lower portions toward the vacuum ports 155 after the gas streams react with the substrate surface. Arrows 198 indicate the direction of the gas streams. Since the partitions 160 operate as a physical barrier to the gas streams, they also limit cross-contamination between the precursors. The arrangement shown is merely illustrative and should not be taken as limiting the scope of the invention. It will be understood by those skilled in the art that the gas distribution system shown is merely one possible distribution system and the other types of showerheads and gas distribution systems may be employed.

In operation, a substrate 60 is delivered (e.g., by a robot) to the load lock chamber 10 and is placed on a carrier 65. After the isolation valve 15 is opened, the carrier 65 is moved along the track 70, which may be a rail or frame system. Once the carrier 65 enters in the processing chamber 20, the isolation valve 15 closes, sealing the processing chamber 20. The carrier 65 is then moved through the processing chamber 20 for processing. In one embodiment, the carrier 65 is moved in a linear path through the chamber.

As the substrate 60 moves through the processing chamber 20, the first surface 61 of substrate 60 is repeatedly exposed to the precursor of compound A coming from gas ports 125 and the precursor of compound B coming from gas ports 135, with the purge gas coming from gas ports 145 in between. Injection of the purge gas is designed to remove unreacted material from the previous precursor prior to exposing the substrate surface 110 to the next precursor. After each exposure to the various gas streams (e.g., the precursors or the purge gas), the gas streams are evacuated through the vacuum ports 155 by the pumping system 150. Since a vacuum port may be disposed on both sides of each gas port, the gas streams are evacuated through the vacuum ports 155 on both sides. Thus, the gas streams flow from the respective gas ports vertically downward toward the first surface 61 of the substrate 60, across the first surface 110 and around the lower portions of the partitions 160, and finally upward toward the vacuum ports 155. In this manner, each gas may be uniformly distributed across the substrate surface 110. Arrows 198 indicate the direction of the gas flow.

Substrate 60 may also be rotated while being exposed to the various gas streams. Rotation of the substrate may be useful in preventing the formation of strips in the formed layers. Rotation of the substrate can be continuous or in discrete steps. Where discrete rotational steps are used, it may be advantageous to rotate the substrate when it is in a position before and/or after the gas distribution plate.

Sufficient space is generally provided at the end of the processing chamber 20 so as to ensure complete exposure by the last gas port in the processing chamber 20. Once the substrate 60 reaches the end of the processing chamber 20 (i.e., the first surface 61 has completely been exposed to every gas port in the chamber 20), the substrate 60 returns back in a direction toward the load lock chamber 10. As the substrate 60 moves back toward the load lock chamber 10, the substrate surface may be exposed again to the precursor of compound A, the purge gas, and the precursor of compound B, in reverse order from the first exposure.

The extent to which the substrate surface 110 is exposed to each gas may be determined by, for example, the flow rates of each gas coming out of the gas port and the rate of movement of the substrate 60. In one embodiment, the flow rates of each gas are configured so as not to remove adsorbed precursors from the substrate surface 110. The width between each partition, the number of gas ports disposed on the processing chamber 20, and the number of times the substrate is passed back and forth may also determine the extent to which the substrate surface 110 is exposed to the various gases. Consequently, the quantity and quality of a deposited film may be optimized by varying the above-referenced factors.

In some embodiments, the system 100 may include a precursor injector 120 and a precursor injector 130, without a purge gas injector 140. Consequently, as the substrate 60 moves through the processing chamber 20, the substrate surface 110 will be alternately exposed to the precursor of compound A and the precursor of compound B, without being exposed to purge gas in between.

The embodiment shown in FIG. 1 has the gas distribution plate 30 above the substrate. While the embodiments have been described and shown with respect to this upright orientation, it will be understood that the inverted orientation is also possible. In that situation, the first surface 61 of the substrate 60 will face downward, while the gas flows toward the substrate will be directed upward.

In one or more embodiments, the system 100 may be configured to process a plurality of substrates. In such an embodiment, the system 100 may include a second load lock chamber (disposed at an opposite end of the load lock chamber 10) and a plurality of substrates 60. The substrates 60 may be delivered to the load lock chamber 10 and retrieved from the second load lock chamber.

The embodiments of FIG. 1 includes at least one laser 171 with a beam of collimated light which is directed along at least one of the elongate gas ports between the gas distribution plate 30 and the substrate 60. As used in this specification and the appended claims, the terms “laser”, “laser beam”, “collimated light”, and the like, are used to describe both the physical hardware associated with generating a laser beam as well as the laser beam itself, depending on the context. As will be well understood by those skilled in the art, stating that the “laser” is directed along the at least one elongate gas ports means that the laser light is directed along the gas ports.

The deposition system 100 includes at least one laser source (not shown) which emits a laser beam. As used in this specification and the appended claims, the term “laser source” means any device capable of emitting a collimated beam of light. Suitable laser sources include, but are not limited to, laser diodes. As used in this specification and the appended claims, the term “laser beam” means a beam of coherent light that that produced from a laser source. The terms “laser beam”, “laser”, “light beam”, “collimated light”, “coherent light”, and the like, are used interchangeably to describe a beam of light emitted by a laser source.

Some precursors require activation before they can be useful in ALD processes. Activation can be as simple as forming an excited species which can react with the substrate surface (or film on the surface) with a lower activation energy barrier. Some precursors require a catalyst for activation and the catalyst can be activated by the laser increasing the catalytic effect. In some embodiments, the laser has sufficient power and frequency to initiate a local plasma. The laser can be used to photolytically produce a useful precursor in the chamber by laser assisted activation of the reactant gases in a region parallel to and adjacent the substrate surface. In some embodiments, the laser light is used to photolytically produce a catalyst species that assists in the activation of reactant gases by directing the laser light parallel to and adjacent the substrate.

Suitable lasers can be continuous wave or pulsed lasers (e.g., nanosecond and femptosecond lasers). The wavelength of the laser can be varied to correspond to the activation energies required by the specific precursors. Ultraviolet, visible, infrared, near-infrared lasers, and others, can be used. For example an argon fluoride (ArF) laser, which emits light at about 193 nm (6.4 eV) may be used to activate ammonia by photolysis to produce NH and NH₂ species. Other exemplary lasers include CO₂ lasers. Additionally, more than one laser type can be employed simultaneously at the same gas injector, or at different gas injectors.

The laser source can be positioned to direct one or more beams of light along any or all of the elongate gas ports. The laser source can be located within the chamber or outside of the chamber. In some embodiments, the laser source is located outside of the chamber to avoid material depositing on the laser's lens. When the laser source is located outside of the chamber, there is a window in at least one wall of the chamber to allow the light beam to enter the processing area. The size and shape of the window can vary depending on the arrangement of laser(s) in the system and the desired path of the laser beam.

Depending on the mode of activation, the precursors being used and the desired film, amongst others, the position of the laser within the chamber. The laser beam can be directed along the length of any of the elongate gas injectors to activate gaseous species flowing from the injector. For example, if the first precursor requires activation, the laser beam can be directed along the front of the first precursor injector, or along the front of all of the first precursor injectors, if there are more than, and it is desired. The laser beam can be directed along any of the precursors injectors, purge gas injectors and vacuum ports as needed. In some embodiments, the laser(s) is directed along the length of one or more of each of the first reactive gas injectors and the at least one second reactive gas injectors.

The laser can be directed along the length of a purge gas injector to convert the otherwise inert gas into a state useful in the formation of a film. For example, a first precursor can be deposited on the substrate surface and then the otherwise inert gas flowing across the surface can activate the surface species before exposure to the second precursor.

The laser beam can be directed in front of the gas distribution plate a distance from the surface of the substrate. The distance from the substrate surface can be varied depending on the precursors. For example, the lifetime of the radicals (activated species) generated by the laser can be a factor in the useful distance from the substrate. When the activated species has a shorter lifetime, the laser beam will be more useful located closer to the substrate surface. In some embodiments, the laser beam is positioned so that when the substrate is present in the system, the laser beam is up to about 100 mm from the substrate surface, or up to about 50 mm from the substrate surface. In some embodiments, the laser beam is up to about 45 mm, 40 mm, 35 mm, 30 mm, 25 mm, 20 mm, 15 mm, 10 mm, 9 mm, 8 mm, 7 mm, 6 mm, 5 mm, 4 mm, 3 mm, 2 mm, 1 mm, or 0.5 mm from the substrate surface. In some embodiments, the laser beam has a width in the range of about 0.5 mm to about 1 m. In one or more embodiments, the laser beam has a width in the range of about 1 mm to about 0.5 m. The width of the beam can be static or dynamic throughout processing. A plurality of lasers can be employed to make the beam wider. The beam can be shaped or manipulated using any known technique including, but not limited to, cylindrical or diffracting optics.

The laser power can be controlled by a separate controller (not shown). The controller can be used to change the power of the laser, including turning the laser on and off, during processing of the substrate. For example, it may be useful to only use the laser for the deposition of the first few ALD layers, at which point the laser can be turned off. Additionally, the controller can power and coordinate multiple lasers, allowing for the rapid switching between lasers during processing. For example, hydrazine can be activated by a UV laser or a hydrogen radical can be generated by an IR laser. The controller is capable of rapidly switching between the UV laser and IR laser to generate both species.

In some embodiments, the carrier 65 is a susceptor 66 for carrying the substrate 60. Generally, the susceptor 66 is a carrier which helps to form a uniform temperature across the substrate. The susceptor 66 is movable in both directions (left-to-right and right-to-left, relative to the arrangement of FIG. 1) between the load lock chamber 10 and the processing chamber 20. The susceptor 66 has a top surface 67 for carrying the substrate 60. The susceptor 66 may be a heated susceptor so that the substrate 60 may be heated for processing. As an example, the susceptor 66 may be heated by radiant heat lamps 90, a heating plate, resistive coils, or other heating devices, disposed underneath the susceptor 66.

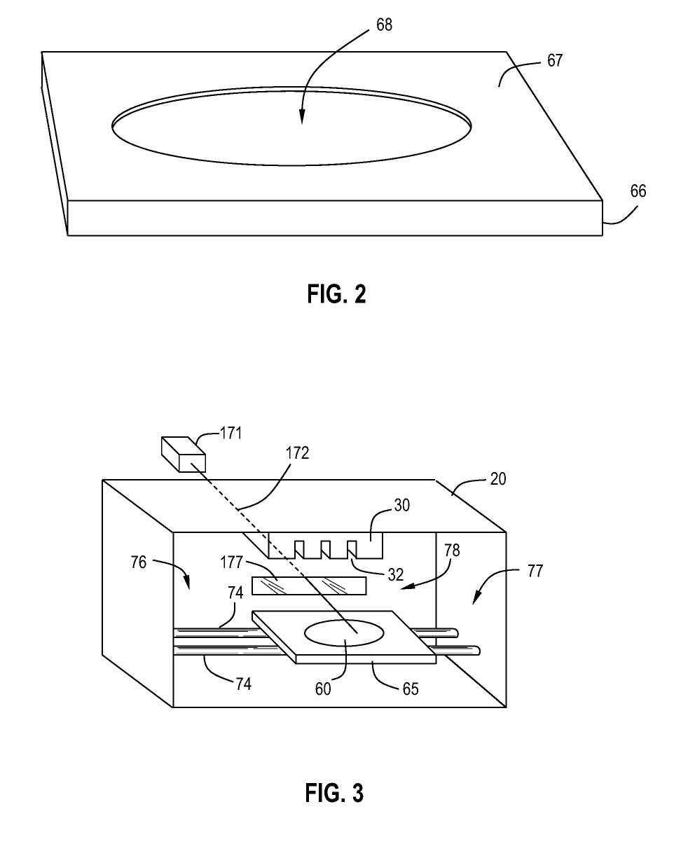

In one or more embodiments, the top surface 67 of the susceptor 66 includes a recess 68 configured to accept the substrate 60, as shown in FIG. 2. The susceptor 66 is generally thicker than the thickness of the substrate so that there is susceptor material beneath the substrate. In some embodiments, the recess 68 is configured such that when the substrate 60 is disposed inside the recess 68, the first surface 61 of substrate 60 is level with the top surface 67 of the susceptor 66. Stated differently, the recess 68 of some embodiments is configured such that when a substrate 60 is disposed therein, the first surface 61 of the substrate 60 does not protrude above the top surface 67 of the susceptor 66.

FIG. 3 shows a partial cross-sectional view of a processing chamber 20 in accordance with one or more embodiments of the invention. The processing chamber 20 has at least one gas distribution plate 30, a window 177 and at least one laser source 171 located outside the chamber 20 directing laser light 172 through the window 177 into the processing chamber 20.

In embodiments with a window 177 there is potential for film deposition on the window 177, as with any other part of the processing chamber. However, deposition on the window 177 could result in, for example, decreased laser intensity reaching the target area (i.e., the gas distribution plate 30), no laser intensity reaching the target area and laser scattering. Therefore, the window 177 of some embodiments is heated to minimize deposition thereon. The window 177 can be heated by any suitable means including, but not limited to, heating lamps directed at the window, heating elements (e.g., ceramic heaters, resistive heaters) located around the edges of the window and ceramic heats directed at the window.

Another embodiment includes a purge gas flow between the window 177 and the gas distribution plate 30. The purge gas flow may help isolate the window 177 from reactive gases from the gas distribution plate 30. To include a purge gas flow, the processing chamber may include one or more of a purge gas source, a purge gas flow controller and a purge gas injector. The flow of the purge gas can be continuous or pulsed. In some embodiments, to maximize the benefit of a purge gas isolating the window, the purge gas flow is continuous. The purge gas flow can be directed anywhere throughout the processing chamber, not just in the area of the window. For example, there can be one or more purge gas flows (i.e., different purge gas injectors) spaced around the entire chamber body to help form a barrier between the gases from the gas distribution plate and the walls of the chamber.

In some embodiments, the processing chamber 20 includes a substrate carrier 65 that moves a substrate along a linear reciprocal path along an axis perpendicular to the elongate gas injectors. As used in this specification and the appended claims, the term “linear reciprocal path” refers to either a straight or slightly curved path in which the substrate can be moved back and forth. Stated differently, the substrate carrier may be configured to move a substrate reciprocally with respect to the gas injector unit in a back and forth motion perpendicular to the axis of the elongate gas injectors. As shown in FIG. 3, the carrier 65 is supported on rails 74 which are capable of moving the carrier 65 reciprocally from left-to-right and right-to-left, or capable of supporting the carrier 65 during movement. Movement can be accomplished by many mechanisms known to those skilled in the art. For example, a stepper motor may drive one of the rails, which in turn can interact with the carrier 65, to result in reciprocal motion of the substrate 60. In some embodiments, the substrate carrier is configured to move a substrate 60 along a linear reciprocal path along an axis perpendicular to and beneath the elongate gas injectors 32. In some embodiments, the substrate carrier 65 is configured to transport the substrate 60 from a region 76 in front of the gas distribution plate 30 to a region 77 after the gas distribution plate 30 so that the entire substrate 60 surface passes through a region 78 occupied by the gas distribution plate 30.

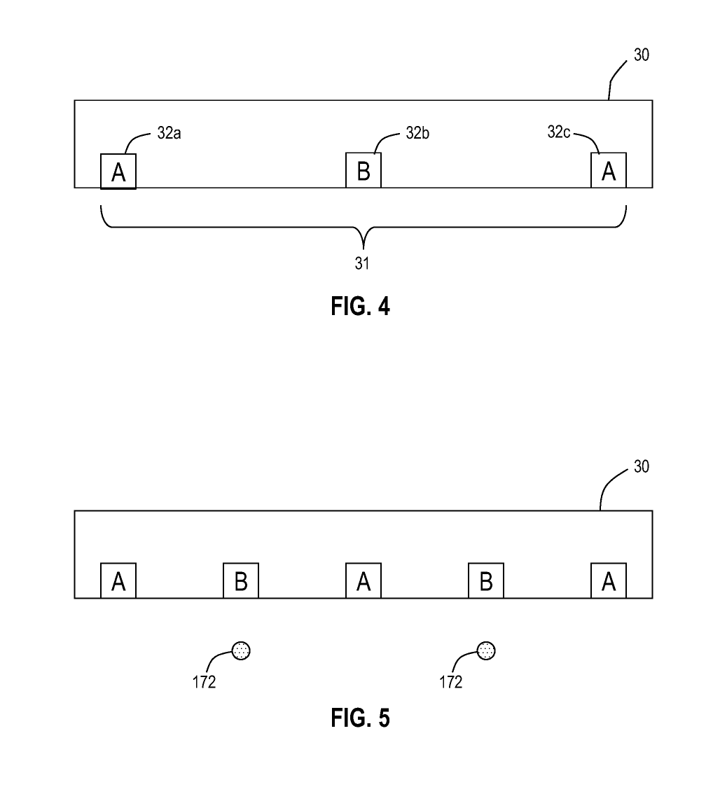

FIGS. 4-9 show side, partial cross-sectional views of gas distribution plates 30 in accordance with one or more embodiments of the invention. The letters used in these drawings represent some of the different gases which may be used in the system. As a reference, A is a first reactive gas, B is a second reactive gas, C is a third reactive gas, P is a purge gas and V is vacuum. As used in this specification and the appended claims, the term “reactive gas” refers to any gas which may react with either the substrate, a film or partial film on the substrate surface. Non-limiting examples of reactive gases include hafnium precursors, tantalum precursors, water, cerium precursors, peroxide, titanium precursors, ozone, plasmas, Groups III-V elements, ammonia and hydrazine. Purge gases are any gas which is non-reactive with the species or surface it comes into contact with. Non-limiting examples of purge gases include argon, nitrogen and helium.

In some embodiments, the reactive gas injectors on either end of the gas distribution plate 30 are the same so that the first and last reactive gas seen by a substrate passing the gas distribution plate 30 is the same. For example, if the first reactive gas is A, then the last reactive gas will also be A. If gas A and B are switched, then the first and last gas seen by the substrate will be gas B.

Referring to FIG. 4, the gas distribution plate 30 of some embodiments comprises a plurality of elongate gas injectors including at least two first reactive gas injectors A and at least one second reactive gas injector B which is a different gas than that of the first reactive gas injectors. The first reactive gas injectors A are in fluid communication with a first reactive gas, and the second reactive gas injectors B are in fluid communication with a second reactive gas which is different from the first reactive gas. Laser beams 172 are directed through the path of the second reactive gas injectors B to activate the gaseous species from these injectors. The at least two first reactive gas injectors A surround the at least one second reactive gas injector B so that a substrate moving from left-to-right will see, in order, the leading first reactive gas A, the second reactive gas B and the trailing first reactive gas A, resulting in a full layer being formed on the substrate. A substrate returning along the same path will see the opposite order of reactive gases, resulting in two layers for each full cycle. As a useful abbreviation, this configuration may be referred to at an ABA injector configuration. A substrate moved back and forth across this gas distribution plate 30 would see a pulse sequence of
AB AAB AAB (AAB)ₙ . . . AABA
   forming a uniform film composition of B. Exposure to the first reactive gas A at the end of the sequence is not important as there is no follow-up by a second reactive gas B. It will be understood by those skilled in the art that while the film composition is referred to as B, it is really a product of the surface reaction products of reactive gas A and reactive gas B and that use of just B is for convenience in describing the films.

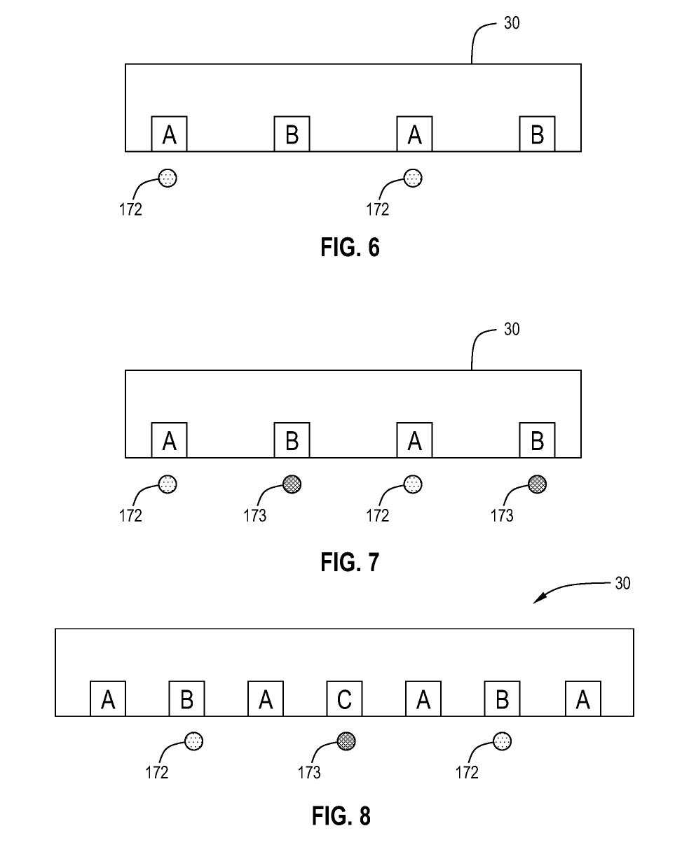

FIG. 5 shows another embodiment similar to that of FIG. 5 in which there are two second reactive gas B injectors, each surrounded by a first reactive gas A injector. A substrate moved back and forth across this gas distribution plate 30 would see a pulse sequence of
ABAB AABAB (AABAB)ₙ . . . AABABA
   forming a uniform film composition of B. As in the embodiment of FIG. 4, laser beams 172 are directed along the path of the second reactive gas B injectors. But it will be understood that the laser beam 172 can be directed along only one of the second reactive gas B injectors or any or all of the first reactive gas A injectors. The main difference between the embodiment of FIG. 6 and FIG. 5 is that each full cycle (one back and forth movement) will result in four layers.

Similarly, FIGS. 6-7 show embodiments of the gas distribution plate 30 without a trailing first reactive gas A injector. In FIG. 6, the laser beams 172 are shown in the path of the gas from the first reactive gas A injectors. In FIG. 7, there are shown laser beams 172 in the path of the first reactive gas A injector and a second laser beam 173 in the path of the second reactive gas B injector

FIG. 8 shows another embodiment of the invention in which the plurality of gas injectors 32 further comprise at least one third gas injector for a third reactive gas C. At least two first reactive gas A injectors surround the at least one third gas reactive gas injector. A substrate moved back and forth across this gas distribution plate 30 would see a pulse sequence of
AB AC AB AAB AC AB (AAB AC AB)ₙ . . . AAB AC ABA
   resulting in a film composition of BCB(BCB)ₙ . . . BCB. Again, the final exposure to the first reactive gas A is not important. Here, a laser beam 172 is shown activating the second reactive gas B and a second laser beam 173, which can be different or the same as the laser beam 172, is shown activating the third reactive gas C. Again, this is merely an example and should not be taken as limiting the scope of the invention.

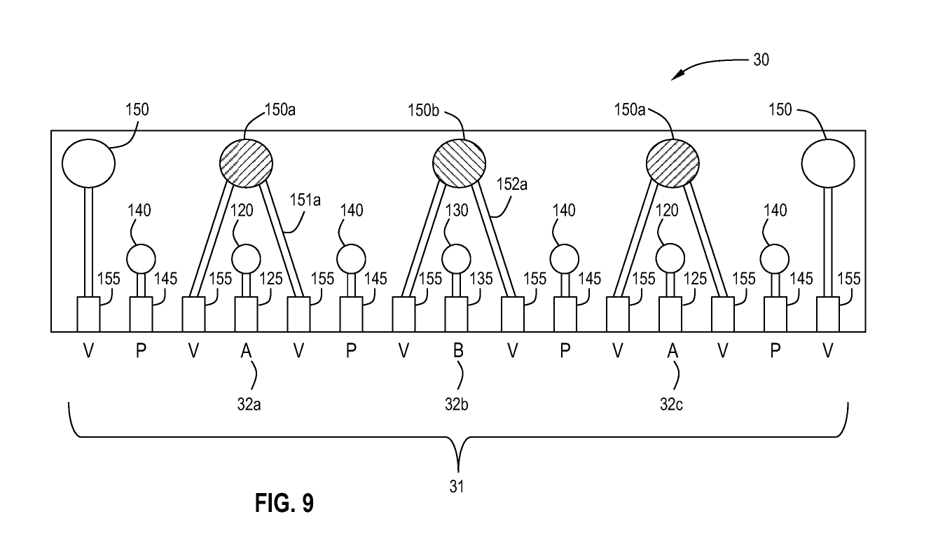

FIG. 9 shows a gas distribution plate 30 comprising purge gas P injectors and outside vacuum V ports. In the embodiment shown, the gas distribution plate 30 comprises at least two pumping plenums connected to the pumping system 150. The first pumping plenum 150a is in flow communication with the vacuum ports 155 adjacent to (on either side of) the gas ports 125 associated with the first reactive gas A injectors 32a, 32c. The first pumping plenum 150a is connected to the vacuum ports 155 through two vacuum channels 151a. The second pumping plenum 150b is in flow communication with the vacuum ports 155 adjacent to (on either side of) the gas port 135 associated with the second reactive gas B injector 32b. The second pumping plenum 150b is connected to the vacuum ports 155 through two vacuum channels 152a. In this manner, the first reactive gas A and the second reactive gas B are substantially prevented from reacting in the gas phase. The vacuum channels in flow communication with the end vacuum ports 155 can be either the first vacuum channel 150a or the second vacuum channel 150b, or a third vacuum channel. The pumping plenums 150, 150a, 150b can have any suitable dimensions. The vacuum channels 151a, 152a can be any suitable dimension. In some embodiments, the vacuum channels 151a, 152a have a diameter of about 22 mm. The end vacuum plenums 150 collect substantially only purge gases. An additional vacuum line collects gases from within the chamber. These four exhausts (A, B, purge gas and chamber) can be exhausted separately or combined downstream to one or more pumps, or in any combination with two separate pumps.

Some embodiments of the invention are directed to an atomic layer deposition system comprising a processing chamber with a gas distribution plate therein. The gas distribution plate comprises a plurality of gas injectors consisting essentially of, in order, a vacuum port, a purge gas injector, a vacuum port, a first reactive gas injector, a vacuum port, a purge port, a vacuum port, a second reactive gas injector, a vacuum port, a purge port, a vacuum port, a first reactive gas injector, a vacuum port, a purge port and a vacuum port. As used in this specification and the appended claims, the term “consisting essentially of”, and the like, mean that the gas injector excludes additional reactive gas injectors, but does not exclude non-reactive gas injectors like purge gases and vacuum lines. Therefore, in the embodiment shown in FIG. 4, the addition of purge gases and/or vacuum ports (see e.g., FIG. 9) would still consist essentially of ABA, while the addition of a third reactive gas C injector (see e.g., FIG. 8) would not consist essentially of ABA.

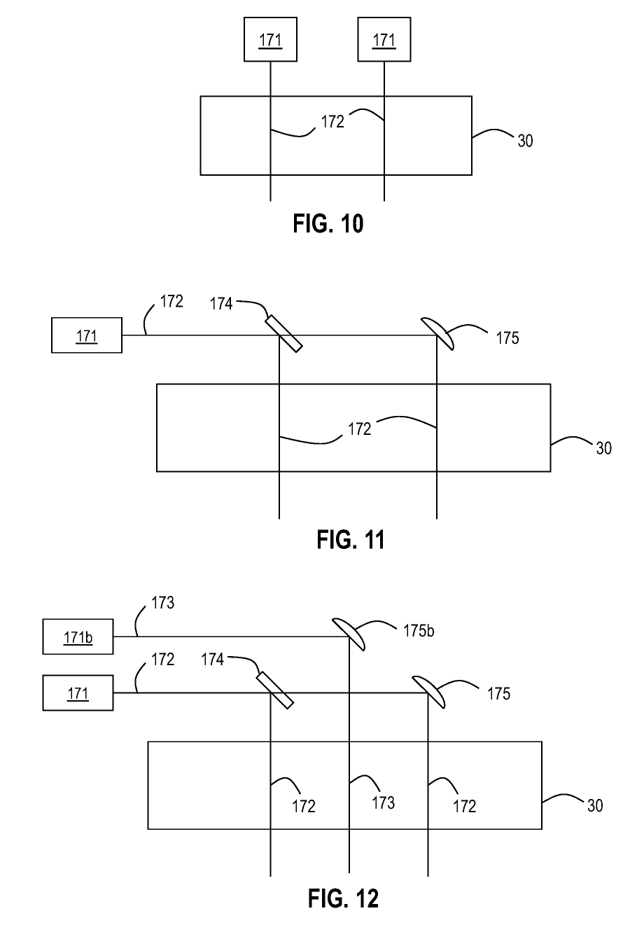

The number and arrangement of the laser sources 171 can vary depending on the specific processing requirement. FIG. 10 shows an embodiment in which there are two separate laser sources 171 emitting two separate laser beams 172 across the gas distribution plate 30. FIG. 11 shows an embodiment in which there is one laser source 171 emitting a single laser beam 172 which is split by beam splitter 174 and one of the split beams if redirected with mirror 175. Both of the split beams 172 are different gas injectors, resulting in a single laser beam being directed along multiple gas injectors by aid of beam splitter. It will be understood by those skilled in the art that the laser power may be adjusted to maintain sufficient energy upon splitting. It will also be understood that there can be additional lenses, mirrors and splitters than what has been illustrated without deviating from the scope of the invention.

FIG. 12 shows another embodiment in which there is a first laser source 171 emitting a first laser beam 172 which is split by splitter 174 and redirected by mirror 175. A second laser source 171b emits a second laser beam 173 which is redirected by mirror 175b. The first and second laser beams 172, 173 are directed across the gas distribution plate at different gas injectors. In some embodiments, the first laser beam 172 and second laser beam 173 are directed along the path of the same gas injector.

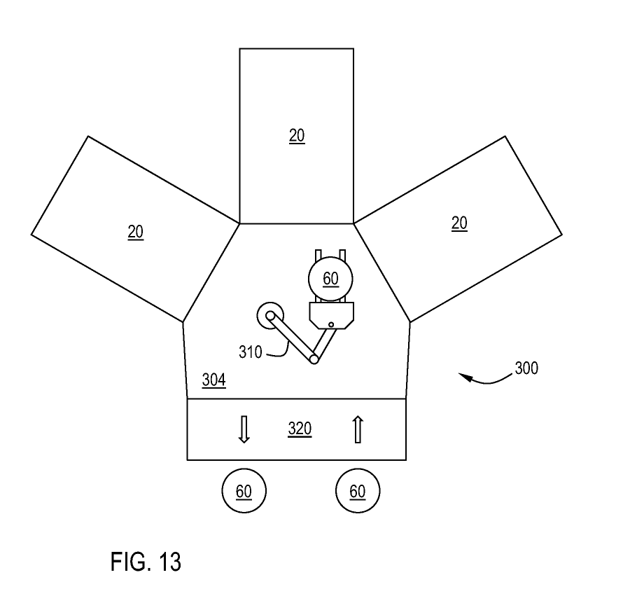

Additional embodiments of the invention are directed to cluster tools comprising at least one atomic layer deposition system described. The cluster tool has a central portion with one or more branches extending therefrom. The branches being deposition, or processing apparatuses. Cluster tools require substantially less space than stand-alone tools. The central portion of the cluster tool may include at least one robot arm capable of moving substrates from a load lock chamber into the processing chamber and back to the load lock chamber after processing. Referring to FIG. 13, an illustrative cluster tool 300 includes a central transfer chamber 304 generally including a multi-substrate robot 310 adapted to transfer a plurality of substrates in and out of the load lock chamber 320 and the various process chambers 20. Although the cluster tool 300 is shown with three processing chambers 20, it will be understood by those skilled in the art that there can be more or less than 3 processing chambers. Additionally, the processing chambers can be for different types (e.g., ALD, CVD, PVD) of substrate processing techniques.

Although the invention herein has been described with reference to particular embodiments, it is to be understood that these embodiments are merely illustrative of the principles and applications of the present invention. It will be apparent to those skilled in the art that various modifications and variations can be made to the method and apparatus of the present invention without departing from the spirit and scope of the invention. Thus, it is intended that the present invention include modifications and variations that are within the scope of the appended claims and their equivalents.

1. A deposition system, comprising:
a processing chamber;
a gas distribution plate in the processing chamber, the gas distribution plate having a plurality of elongate gas ports to direct flows of gases toward a surface of a substrate, and
at least one laser source emitting a laser beam directed along at least one of the elongate gas ports between the gas distribution plate and the substrate.

2. The deposition system of claim 1, wherein the gas distribution plate comprises a plurality of first reactive gas injectors to direct flows of a first reactive gas toward a substrate and at least one second reactive gas injector to direct a flow of a second reactive gas different from the first reactive gas toward a substrate.

3. The deposition system of claim 2, wherein the at least one laser beam is directed along a length of one or more of each of the first reactive gas injectors and the at least one second reactive gas injectors.

4. The deposition system of claim 1, wherein there is one laser source.

5. The deposition system of claim 4, further comprising at least one beam splitter to split the laser beam along multiple elongate gas injector.

6. The deposition system of claim 1, wherein there are at least two laser sources emitting laser beams and each laser beam is directed along a different elongate gas injector.

7. The deposition system of claim 1, wherein the at least one laser source is positioned so that when a substrate is present in the system, the laser beam is up to about 50 mm from the substrate.

8. The deposition system of claim 1, wherein the laser beam is one of a continuous laser and a pulsed laser.

9. The deposition system of claim 1, wherein the laser source is located outside of the processing chamber and the laser beam is directed through a window in a wall of the processing chamber.

10. The deposition system of claim 9, wherein the window is heated.

11. The deposition system of claim 9, further comprising a purge gas flow between the window and the gas distribution plate.

12. A deposition system, comprising:
a processing chamber;
a gas distribution plate in the processing chamber to direct flows of gases toward a surface of a substrate, and
at least one laser source emitting a laser beam directed along a path adjacent the gas distribution plate between the gas distribution plate and the substrate.

13. The deposition system of claim 12, wherein there is one laser source and the system further comprises at least one beam splitter to direct the one laser beam along multiple paths.

14. The deposition system of claim 12, wherein there are at least two lasers sources emitting at least two laser beams.

15. The deposition system of claim 14, further comprising at least one beam splitter that directs at least one of the at least two lasers beams along multiple paths.

16. The deposition system of claim 12, wherein the at least one laser source is positioned so that when a substrate is present in the system, the laser beam is up to about 50 mm from the substrate.

17. The deposition system of claim 12, wherein the laser beam is one of a continuous laser and a pulsed laser.

18. A method of processing a substrate comprising:
sequentially contacting the substrate with a flow of a first reactive gas and a flow of a second reactive gas from a gas distribution plate to form a layer on the substrate, the gas distribution plate comprising a plurality of elongate gas injectors; and
activating at least one of the first reactive gas and the second reactive gas with at least one laser beam directed adjacent the gas distribution plate.

19. The method of claim 18, wherein each of the first reactive gas and second reactive gas flow from separate elongate gas injectors and the at least one laser beam is directed along a length of at least one of the elongate gas injectors.

20. The method of claim 18, further comprising pulsing the laser beam to coincide with the flow of one or more of the first reactive gas and the second reactive gas.
